(19) United States
(12) Patent Application Publication
(10) Pub. No.: US 2015/0372590 A1
(43) Pub. Date: Dec. 24, 2015

(54) CHARGE PUMP, POTENTIAL CONVERSION CIRCUIT AND SWITCHING CIRCUIT

(71) Applicant: KABUSHIKI KAISHA TOSHIBA, Tokyo (JP)

(72) Inventor: Toshiki SESHITA, Kawasaki (JP)

(21) Appl. No.: 14/634,404

(22) Filed: Feb. 27, 2015

(30) Foreign Application Priority Data
Jun. 23, 2014 (JP) 2014-128600

(51) Int. Cl. H02M 3/07; H03K 3/03; H03K 5/08

(52) U.S. Cl. CPC H02M 3/07; H03K 5/08; H03K 3/0315

(57) ABSTRACT

A charge pump includes a positive potential generation circuit that generates a positive potential, and a negative potential generation circuit that generates a negative potential. The positive potential generation circuit includes rectifying elements connected in series between a reference potential node and an output node, and capacitors are connected to a node between each adjacent pair of rectifying elements and to one of a first and second clock signal port. The negative potential generation circuit includes rectifying elements connected in series between the reference potential node and the output node in an opposite direction to that of the first rectifying elements. Capacitors are connected to a node between each adjacent pair of rectifying element in the negative potential generation circuit and one of a third and fourth clock signal port.

### CROSS-REFERENCE TO RELATED APPLICATION

This application is based upon and claims the benefit of priority from Japanese Patent Application No. 2014-128600, filed Jun. 23, 2014, the entire contents of which are incorporated herein by reference.

### FIELD

Exemplary embodiments described herein relate to a charge pump, a potential conversion circuit, and a switching circuit.

### BACKGROUND

In a high-frequency circuit unit of a portable terminal device such as a cellular phone or a smartphone, a transmitting circuit and a receiving circuit are configured to use a common antenna using a high-frequency signal switching circuit selectively connecting the transmitting and receiving circuits to the common antenna). Generally, HEMTs (High Electron Mobility Transistors) using compound semiconductors have been used in the high-frequency signal switching circuit. The replacement of HEMTs with MOSFETs (Metal Oxide Semiconductor Field Effect Transistors) formed on a silicon substrate has been recently studied for high-frequency signal switching circuits to reduce component prices and sizes.

However, a parasitic capacitance between a source/drain electrode and the silicon substrate is large for MOSFETs formed on a normal silicon substrate. The large parasitic capacitance causes significant power loss of a high-frequency signal being transmitted or received. Consequently, a technique has been proposed in which a high-frequency switching circuit including MOSFETs is formed on an SOI (Silicon On Insulator) substrate.

In a high-frequency switching circuit including a MOSFET it is necessary to apply different gate potentials sufficient to place the MOSFET in a conductive state (ON-state) and in a non-conductive state (OFF-state) across its source-drain terminals. Additionally, to reduce the ON-state resistance of the MOSFET, the applied gate potential is generally higher than a simple threshold voltage. In addition, the off-potential thereof is a gate potential capable of sufficiently maintaining a cut-off state even when the MOSFET is set to be in a cut-off state and high-frequency signals are superimposed. Thus, when the applied gate potential is lower than a desired potential (for example, 3 V), the on-resistance of a FET within the high-frequency switch increases, and an insertion loss and on-distortion increase. In addition, when the off-potential is higher than a desired potential (for example, −2 V), maximum permissible input power decreases and thus off-distortion increases.

A level shifter, for example, is used for generating a desired potential for application to a gate of a high frequency signal switch. However, since a FET in the level shifter may not have a high breakdown voltage, the FET may breakdown depending on the potential level of a desired potential.

### DESCRIPTION OF THE DRAWINGS

FIG. 1 is a block diagram illustrating a schematic configuration of a switching circuit including a charge pump and a potential conversion circuit according to a first embodiment.

FIG. 2 is a circuit diagram illustrating an internal configuration of a first clock generator and a second clock generator.

FIG. 3 is a circuit diagram illustrating an example an internal configuration of the charge pump.

FIG. 4A is a signal waveform diagram of a control signal which is input to the switching circuit, and FIG. 4B is a signal waveform diagram of an output signal of the charge pump.

FIG. 5A is a block diagram illustrating an example in which a positive potential clamping circuit is connected to an output node of the potential conversion circuit.

FIG. 5B is a block diagram illustrating an example in which a negative potential clamping circuit is connected to the output node of the potential conversion circuit.

FIG. 6A is a signal waveform of the control signal as that in FIG. 4A, and FIG. 6B is a diagram illustrating an output signal waveform of the charge pump when the positive potential clamping circuit is provided.

FIG. 7 is a diagram illustrating an example a high-frequency switching unit having an internal configuration different from a high-frequency switching unit of FIG. 1.

FIG. 8 is a block diagram illustrating a schematic configuration of a switching circuit according to a second embodiment.

FIG. 9 is a circuit diagram illustrating an internal configuration of an oscillator.

FIG. 10 is a first modified example of the switching circuit of FIG. 8, and is a diagram in which the positive potential clamping circuit is connected to the output node OUT of the potential conversion circuit.

FIG. 11 is a second modified example of the switching circuit of FIG. 8, and is a diagram in which a diode is connected between the body and the gate of each FET within the switching circuit.

FIG. 12 is a circuit diagram illustrating a detailed configuration of a high-frequency switching unit according to a third embodiment.

FIG. 13 is a block diagram illustrating a potential conversion circuit and its peripheral circuits according to the third embodiment.

FIG. 14 is a circuit diagram illustrating an example of an internal configuration of a level shifter.

FIG. 15 is a circuit diagram illustrating a detailed configuration of a high-frequency switching unit according to a fourth embodiment.

FIG. 16 is a block diagram illustrating a potential conversion circuit and peripheral circuits according to the fourth embodiment.

### DETAILED DESCRIPTION

Embodiments provide a charge pump and a potential conversion circuit having a small restriction on a breakdown voltage, and a switching circuit having little harmonic distortion.

According to an example embodiment, a charge pump comprises a positive potential generation circuit connected between a reference potential node (e.g., ground node) and an output node. The positive potential generation circuit includes a first plurality of rectifying elements (e.g., diodes) connected in series between the reference potential node and the output node. Each adjacent pair of rectifying elements in the first plurality has a capacitor with a first end connected to a node between the adjacent pair and, for a first group of adjacent pairs, a second end of the capacitor is connected to a first clock signal port and, for a second group of adjacent pairs, a second end of the capacitor is connected to a second clock signal port. The adjacent pairs in the first and second groups alternate in series with each other. A negative potential generation circuit in the charge pump is connected between the reference potential node and the output node. The negative potential generation circuit includes a second plurality of rectifying elements connected in series between the reference potential node and the output node. Each adjacent pair of rectifying elements in the second plurality has a capacitor with a first end connected to a node between the adjacent pair and, for a first group of adjacent pairs, a second end of the capacitor is connected to a third clock signal port and, for a second group of adjacent pairs, a second end of the capacitor is connected to a fourth clock signal port. The adjacent pairs in the first and second groups within the negative potential generation circuit alternate in series with each other. The first and second plurality of rectifying elements are connected in opposite directions between the output node and the ground node. That is, for example the first plurality are connected anode to cathode from the ground node side to the output node side and the second plurality are connected cathode to anode from the ground node side to the output node side.

According to an exemplary embodiment, a charge pump includes: a positive potential generation circuit, connected between a reference potential node and an output node, that generates a positive potential; and a negative potential generation circuit, connected between the reference potential node and the output node, that generates a negative potential, wherein the positive potential generation circuit includes: multiple stages of first rectifying elements that are connected in series to each other between the reference potential node and the output node; a first capacitor and a second capacitor of which respective one ends are alternately connected to each other between stages of the multiple stages of first rectifying elements; a first port that supplies a first clock signal to the other end of the first capacitor; and a second port that supplies a second clock signal, having an opposite phase to a phase of the first clock signal, to the other end of the second capacitor, and wherein the negative potential generation circuit includes: multiple stages of second rectifying elements that are connected in series to each other between the reference potential node and the output node in an opposite direction to a direction of the multiple stages of first rectifying elements; a third capacitor and a fourth capacitor of which respective one ends are alternately connected to each other between stages of the multiple stages of first rectifying elements; a third port that supplies a third clock signal to the other end of the third capacitor; and a fourth port that supplies a fourth clock signal, having an opposite phase to a phase of the third clock signal, to the other end of the fourth capacitor.

Hereinafter, exemplary embodiments will be described with reference to the accompanying drawings. In the following embodiments, a description will focus on the characteristic configurations and operations within a charge pump, a potential conversion circuit, and a switching circuit, with various configuration and operation details being omitted. However, these omitted details will be apparent to those of ordinary skill in the art and are thus also included in the scope of the present disclosure.

### First Embodiment

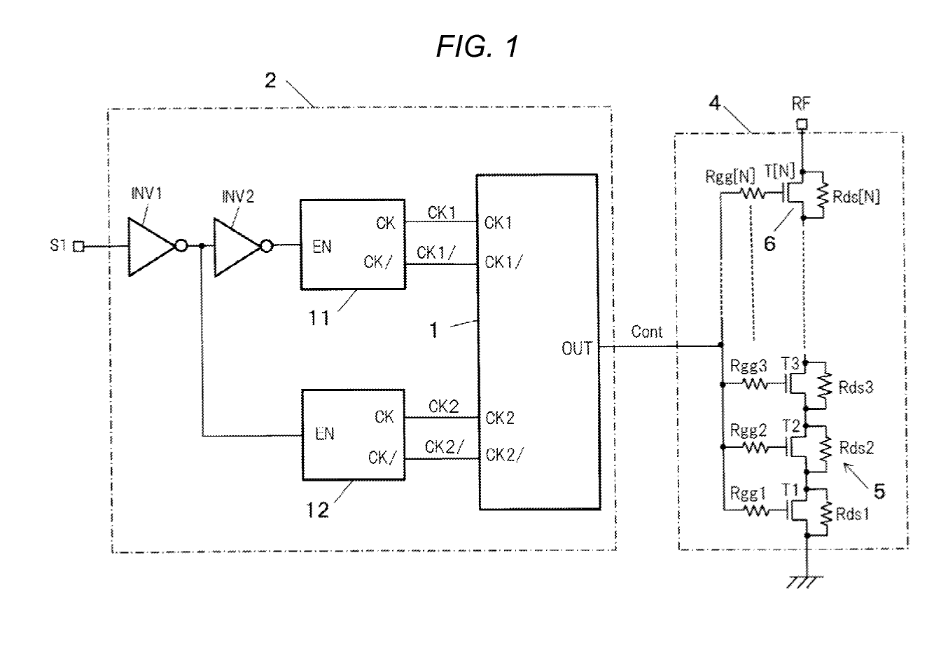

FIG. 1 is a block diagram illustrating a schematic configuration of a switching circuit including a charge pump 1 and a potential conversion circuit 2 according to a first embodiment. The switching circuit of FIG. 1 includes the potential conversion circuit 2 and a high-frequency switching unit 4.

The high-frequency switching unit 4 includes a shunt FET group 5 which is connected between a high-frequency signal node RF and a ground node. The shunt FET group 5 is turned on or turned off in accordance with an output potential of the potential conversion circuit 2. The shunt FET group 5 short-circuits (connects) the high-frequency signal node RF and the ground node when placed in an on-state, and cuts off (disconnects) the high-frequency signal node RF and the ground node when placed in an off-state.

The shunt FET group 5 includes a plurality of FETs 6 which are connected in series to each other between the high-frequency signal node RF and the ground node. The plurality of FETs 6 are provided for suppressing a voltage applied between the drain and the source of one FET 6 to a breakdown voltage or lower of the FET 6. The gate of each FET 6 is connected to an output node of the potential conversion circuit 2 through respective impedance elements Rgg1 to [N]. In addition, an impedance element Rds1 to [N] is connected between the drain and the source of each FET 6. The impedance elements Rds1 to [N] are provided so that a drain-to-source voltage does not become unfixed at the time of turn-off of the FET 6.

The high-frequency switching unit 4 of FIG. 1 is provided with only one shunt FET group 5, and the potential conversion circuit 2 switches all the FETs 6 within the shunt FET group 5 on or off at the same time. That is, the gate of each FET 6 in FIG. 1 is commonly connected to the output node of the potential conversion circuit 2.

The potential conversion circuit 2 converts the potential level of a control signal (at S1) which is input from the outside of the switching circuit, and generates a switching control signal Cont for switching the shunt FET group 5 between on and off states.

The potential conversion circuit 2 includes inverters INV1 and INV2, a first clock generator 11, a second clock generator 12, and charge pump 1.

The inverters INV1 and INV2 are connected in two-stage series to each other. The output of the post-stage inverter INV2 is supplied to the first clock generator 11, and the output of the pre-stage inverter INV1 is supplied to the second clock generator 12.

The first clock generator 11 performs an oscillation operation when a control signal S1 is a first logic level and generates a first clock signal CK1 and a second clock signal CK1/ having phases that are inverted from each other. The second clock generator 12 performs an oscillation operation when the control signal S1 is a second logic level, and generates a third clock signal CK2 and a fourth clock signal CK2/ having phases that are inverted from each other.

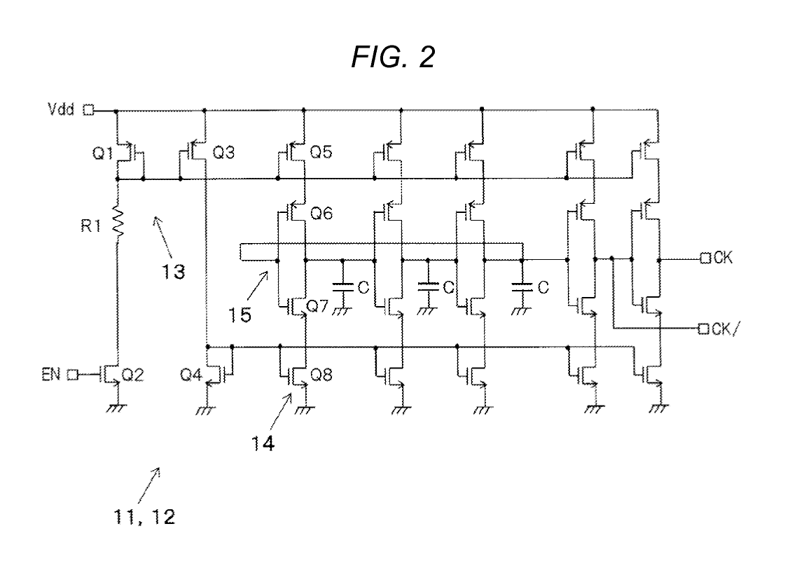

The internal configurations of the first clock generator 11 and the second clock generator 12 are the same as each other, and may be, for example, a circuit as illustrated in FIG. 2. The circuit of FIG. 2 includes a current mirror unit 13 and five-stage logic inversion units 14 which are connected in series to each other.

The current mirror unit 13 causes a current to flow depending on the logic of a control signal port EN. The current mirror unit 13 includes a PMOS transistor Q1, an impedance element R1 and an NMOS transistor Q2 which are connected in series to each other between the node of a power supply potential Vdd and the ground node, a PMOS transistor Q3 which is connected to the PMOS transistor Q1 in a current mirror manner, and an NMOS transistor Q4 which is connected between the drain of the PMOS transistor Q3 and the ground node.

The initial three stages of the five-stage logic inversion units 14 configure a ring oscillator 15. A capacitor C is connected between the output node of each logic inversion unit 14 within the ring oscillator 15 and the ground node. The output node of the logic inversion unit 14 located at a third stage from the head is connected to the input node of the first-stage logic inversion unit 14. The second clock signal CK1/ or the fourth clock signal CK2/ is output from the output node of the logic inversion unit 14 located at a fourth stage on the post-stage side of the ring oscillator 15, and the first clock signal CK1 or the third clock signal CK2 is output from the output node of the logic inversion unit 14 located at a fifth stage thereof.

Each of the logic inversion units 14 includes four transistors Q5 to Q8 which are connected in series to each other between the node of the power supply potential Vdd and the ground node. The conductivity types of these transistors are a PMOS transistor Q5, a PMOS transistor Q6, an NMOS transistor Q7, and an NMOS transistor Q8, in order from the side closer to the node of the power supply voltage Vdd. The PMOS transistor Q5 configures the PMOS transistor Q1 and a current mirror circuit within the current mirror unit 13. Thus, a current proportional to the PMOS transistor Q1 flows to the PMOS transistor Q5. In addition, the NMOS transistor Q8 configures the NMOS transistor Q4 and a current mirror circuit. Thus, a current proportional to the NMOS transistor Q4 flows to the NMOS transistor Q8.

When the control signal port EN is high (e.g., first logic level), a current flows to the current mirror unit 13. Therefore, the ring oscillator 15 performs an oscillation operation, and the first clock signal CK1 (third clock signal CK2) and the second clock signal CK1/ (fourth clock signal CK2/) are output. When the control signal port EN is low (e.g., second logic level), a current does not flow to the current mirror unit 13. Therefore, a current also does not flow to the logic inversion unit 14, and the ring oscillator 15 stops the oscillation operation.

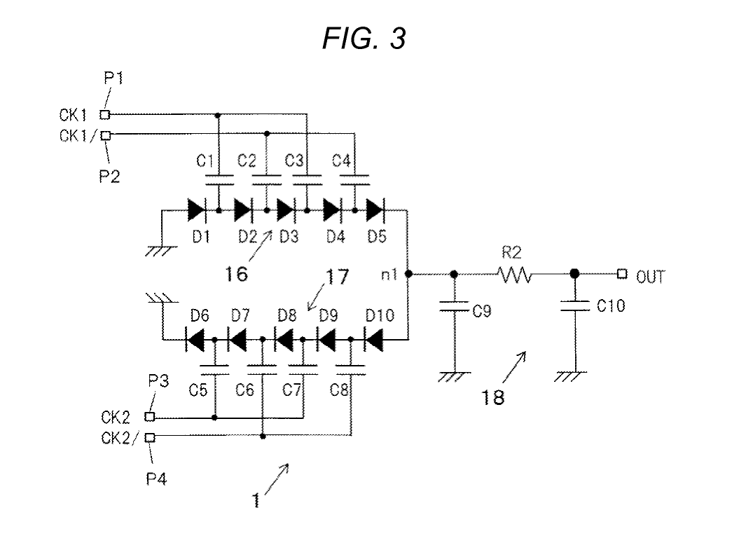

FIG. 3 is a circuit diagram illustrating an example of an internal configuration of the charge pump 1. The charge pump 1 of FIG. 3 includes a positive potential generation circuit 16 and a negative potential generation circuit 17.

The positive potential generation circuit 16 is connected between a reference potential node (for example, ground node) and an output node n1, and generates a positive potential by performing a charge pump operation in synchronization with the first clock signal CK1 and the second clock signal CK1/.

The negative potential generation circuit 17 is connected between the reference potential node (for example, ground node) and the output node n1, and generates a negative potential by performing a charge pump operation in synchronization with the third clock signal CK2 and the fourth clock signal CK2/.

More specifically, the positive potential generation circuit 16 includes multiple stages of diodes (first rectifying elements) D1 to D5 which are connected in series to each other between the ground node and the output node n1. First capacitor C1 is connected between port P1 (first clock signal CK1 node) and a node between diode D1 and diode D2. First capacitor C3 is connected between port P1 and a node between diode D3 and diode D4. Second capacitor C2 is connected between port P2 (second clock signal CK1/) and a node between diode D2 and diode D3. Second capacitor C4 is connected between port P2 and a node between diode D4 and diode D5. The first and second capacitors alternate with each other in connections between the stages of the multiple stages of diodes D1 to D5. Port P1 supplies the first clock signal CK1 to the first capacitors C1 and C3, and port P2 supplies the second clock signal CK1/ to the second capacitors C2 and C4.

In addition, the negative potential generation circuit 17 includes multiple stages of diodes (third rectifying elements) D6 to D10 which are connected in series to each other between the ground node and the output node n1 in an opposite direction to that of the diodes D1 to D5 within the positive potential generation circuit 16. Third capacitors C5 and C7 and fourth capacitors C6 and C8 are alternately connected between the stages of diodes D6 to D10 such that third capacitor C5 is connected to a node between diode D6 and D7, fourth capacitor C6 is connected to a node between diode D7 and diode D8, third capacitor C7 is connected to a node between diode D8 and diode D9, and fourth capacitor C8 is connected to a node between diode D9 and diode D10. Each third capacitor (C5 and C7) is connected to a port P3 that supplies the third clock signal CK2. Each fourth capacitor is connected to a port P4 that supplies the fourth clock signal CK2/. The number of diodes in the positive potential generation circuit 16 is not limited to five and the number of first and second capacitors may be varied accordingly. Similarly, the number of diodes in the negative potential generation circuit 16 is not limited to five and the number of third and fourth capacitors may be varied accordingly.

The positive potential generation circuit 16 and the negative potential generation circuit 17 within the charge pump 1 perform a charge pump operation in synchronization with the first clock signal CK1, the second clock signal CK1/, the third clock signal CK2, and the fourth clock signal CK2/, and thus an instantaneous current flows when the logic of each clock signal is switched. This current flow becomes a factor in harmonic noise generation. Consequently, as illustrated in FIG. 3, it is preferable to connect a low-pass filter 18 to the output node n1 of the charge pump 1. The low-pass filter 18 includes, for example, an impedance element R2 which is connected between the common output node n1 of the positive potential generation circuit 16 and the negative potential generation circuit 17 and the final output node OUT, a capacitor C9 which is connected between the common output node n1 and the ground node on the common output node 1 side of impedance element R2, and a capacitor C10 which is connected on the output node OUT side of impedance element R2 between the final output node OUT and the ground node.

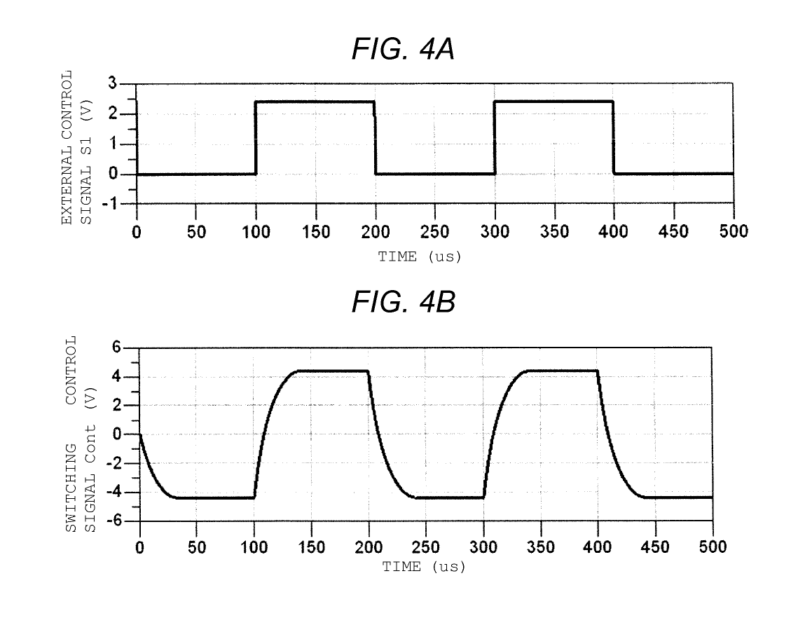

FIG. 4A is a signal waveform diagram of the control signal S1 which is input to the switching circuit of FIG. 1. FIG. 4B is a signal waveform diagram of the output signal of the charge pump 1 (e.g., the signal output at output node OUT). The high voltage of the control signal S1 is approximately 2.3 V, and the low voltage thereof is approximately 0 V, whereas the high voltage of the output signal of the charge pump 1 is approximately 4.1 V, and the low voltage thereof is approximately −4.1 V.

When the control signal S1 is high (first logic level), the first clock generator 11 generates the first clock signal CK1 and the second clock signal CK1/, and the second clock generator 12 does not generate the third clock signal CK2 and the fourth clock signal CK2/. Thereby, the positive potential generation circuit 16 within the charge pump 1 performs a charge pump operation in synchronization with the first clock signal CK1 and the second clock signal CK1/, and a positive potential is output from the output node n1. In this state, the negative potential generation circuit 17 does not perform a charge pump operation because third clock signal CK2 and fourth clock signal CK2/ are not being supplied. Each of the diodes D6 to D10 within the negative potential generation circuit 17 is connected in series between the output node n1 and the ground node. The diodes D6 to D10 are connected in series cathode to anode (from the ground node side to the output node side) with the anode of diode D10 connected to common output node n1 and the cathode of diode D6 connected to the ground node. When the forward drop voltage of the diodes D6 to D10 is set to Vf, the absolute value of the potential of the output node n1 is clamped (restricted) to equal the following: (the number of stages of the diodes within the negative potential generation circuit 17)×forward drop voltage Vf.

In this manner, when the positive potential generation circuit 16 within the charge pump 1 performs a charge pump operation, the potential of the output node n1 of the charge pump 1 is clamped by the number of connection stages of the diodes D6 to D10 within the negative potential generation circuit 17.

On the other hand, when the control signal S1 is low (second logic level), the first clock generator 11 stops generating the first clock signal CK1 and the second clock signal CK1/, and the second clock generator 12 generates the third clock signal CK2 and the fourth clock signal CK2/. Thereby, the negative potential generation circuit 17 within the charge pump 1 performs a charge pump operation in synchronization with the third clock signal CK2 and the fourth clock signal CK2/, and a negative potential is output from the output node n1. In this state, the positive potential generation circuit 16 does not perform a charge pump operation. However, each of the diodes D1 to D5 within the positive potential generation circuit 16 is connected in series between the output node n1 and the ground node. The diodes D1 to D5 are connected in series cathode to anode (from the common node side to the ground node side) between common output node n1 and the ground node, with the cathode of diode D5 connected to the common output node n1 and the anode of diode D1 connected to the ground node. When the forward drop voltage of the diodes D1 to D5 is set to Vf, the absolute value of the potential of the output node n1 is clamped (restricted) to equal the following: (the number of stages of the diodes within the positive potential generation circuit 16)×forward drop voltage Vf.

The low-pass filter 18 is connected to the output node n1. Therefore, for both the positive potential generated by the positive potential generation circuit 16 and the negative potential generated by the negative potential generation circuit 17, harmonic noise is removed by the low-pass filter 18.

In this manner, the charge pump 1 of FIG. 3 switches and generates a positive potential and/or a negative potential in accordance with the logic of the control signal S1. Therefore, the positive potential and the negative potential may be alternately output from one output node n1, and only one low-pass filter 18 is used to filter output noise. Thus, it is possible to reduce a circuit area by not providing a separate low-pass filter 18 for both of the positive potential generation circuit 16 and the negative potential generation circuit 17.

In addition, since the charge pump 1 of FIG. 3 does not use an active component such as a transistor, and is configured only with diodes and capacitors, there is no breakdown voltage restriction would be the case in a level shifter incorporating transistor components. Thus, the charge pump may increase the absolute values of the positive potential and the negative potential, and is suitable for generating a switching control signal Cont for a switching circuit that switches a high-frequency signal.

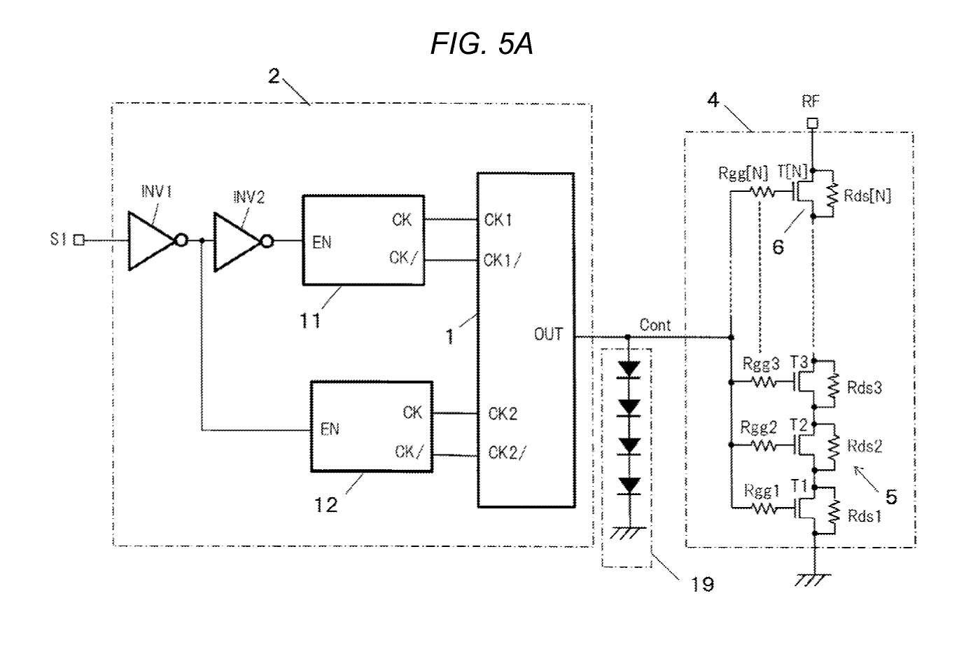

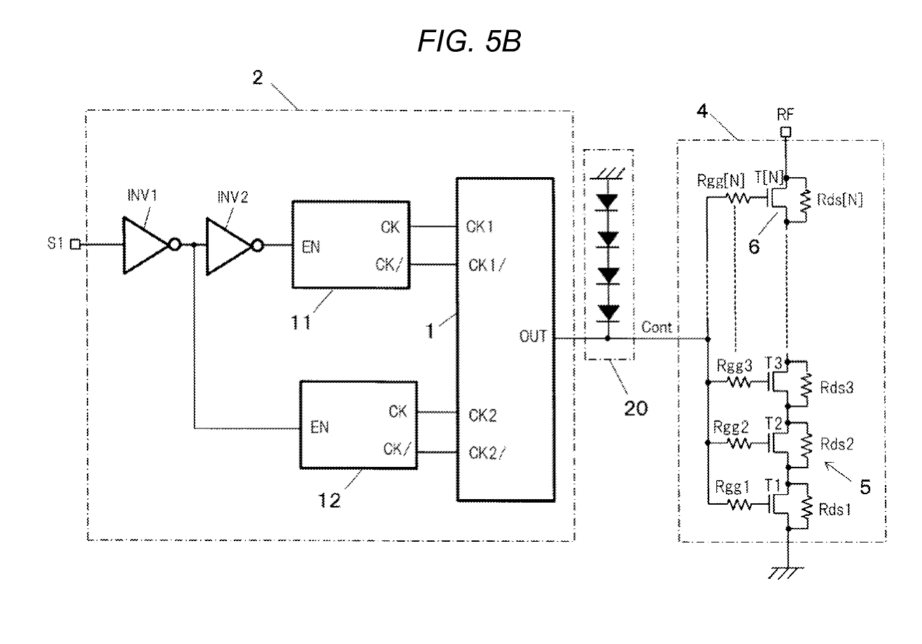

As described above, the potential levels of the positive potential and the negative potential generated by the charge pump 1 of FIG. 3 depend on the number of connection stages of the diodes within the positive potential generation circuit 16 and the negative potential generation circuit 17. When the positive potential of a potential level different from the potential level depending on the number of connection stages of the diodes is output, a positive potential clamping circuit 19 may be connected to the output node OUT of the potential conversion circuit 2 as illustrated in FIG. 5A. The positive potential clamping circuit 19 of FIG. 5A includes a plurality of diodes which are connected in series to each other between the output node n1 and the ground node. The anodes of these diodes are directed to the output node n1 side. When the forward drop voltage of the diodes is set to Vf, and the number of connection stages of the diodes is set to m, the positive potential which is output from the output node n1 is clamped (restricted) to Vf×m. In this case, m is smaller than the number of connection stages of the diodes within the negative potential generation circuit.

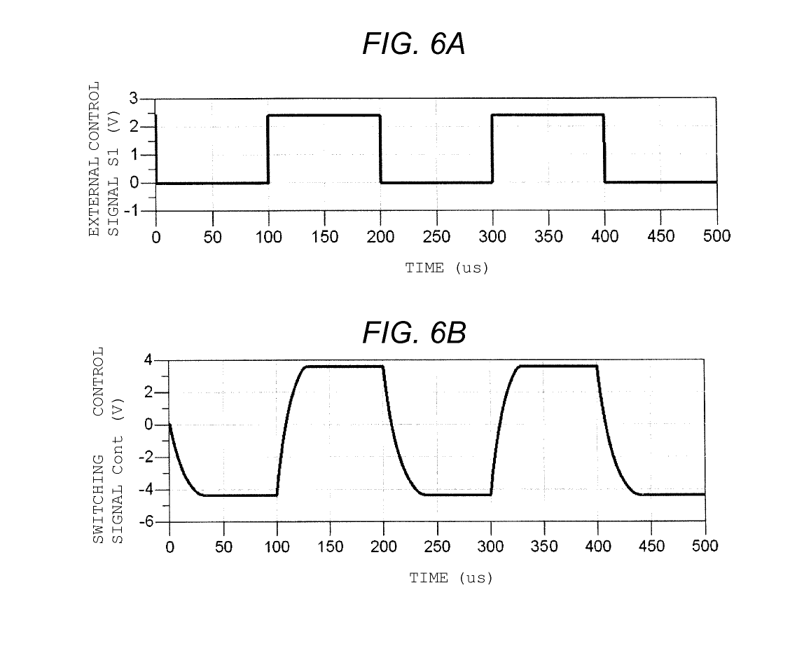

FIG. 6A is a signal waveform of the control signal S1 as that in FIG. 4A, and FIG. 6B is a diagram illustrating an output signal waveform of the charge pump 1 when the positive potential clamping circuit 19 is provided. As may be understood from the comparison of FIG. 6B with FIG. 4B, the potential level of the positive potential is reduced by providing the positive potential clamping circuit 19.

On the other hand, FIG. 5B is a diagram illustrating an example in which a negative potential clamping circuit 20 is connected to the output node OUT of the potential conversion circuit 2. The negative potential clamping circuit 20 includes a plurality of diodes which are connected in series to each other between the ground node and the output node n1. The cathodes of these diodes are directed to the output node n1 side. When the forward drop voltage of the diode is set to Vf, and the number of connection stages of the diodes is set to m, the absolute value of the negative potential which is output from the output node n1 is clamped (restricted) to Vf×m. In this case, m is smaller than the number of connections stages of the diodes within the positive potential generation circuit.

Both the positive potential clamping circuit 19 illustrated in FIG. 5A and the negative potential clamping circuit 20 illustrated in FIG. 5B may be connected to the output node OUT of the potential conversion circuit 2. That is, a switching circuit may include both positive potential clamping circuit 19 and negative potential clamping circuit 20 at the same time.

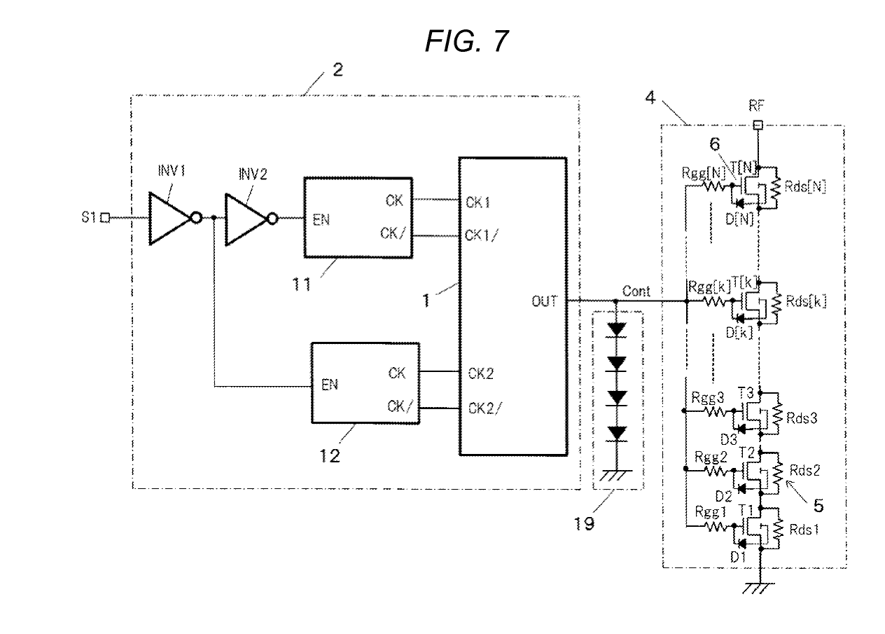

FIG. 7 is a diagram illustrating an example in which a portion of an internal configuration of a high-frequency switching unit 4 is made to be different from the high-frequency switching unit 4 of FIG. 1. Each FET 6 within the high-frequency switching unit 4 of FIG. 7 includes a diode D[k] (k=1 to N) which is connected between the body and the gate. The anode of the diode D[k] is connected to the body, and the cathode thereof is connected to the gate. By providing such a diode D[k], a potential relationship between the gate and the body becomes obvious, and the on and off characteristics of FET 6 are improved. Thus, it is possible to reduce the number of connection stages of the FETs in the shunt FET group 5.

In this manner, in the first embodiment, since the positive potential generation circuit 16 and the negative potential generation circuit 17 in which the output node n1 is used in common are provided within the charge pump 1, and any one of positive potential generation circuit 16 and the negative potential generation circuit 17 is switched and brought into operation in accordance with the logic of the control signal S1, the positive potential and the negative potential may be alternately outputted from the output node n1. Thus, harmonic noise included in the positive potential and the negative potential may be removed only by one low-pass filter 18 which is connected to the output node n1. In addition, the positive potential generation circuit 16 and the negative potential generation circuit 17 may be configured only with the diodes D1 to D10 and the capacitors C1 to C8. Therefore, these circuits may increase the amplitudes of the positive potential and the negative potential without a problem of a breakdown voltage occurring at the time of potential conversion, and are suitable for generating the switching control signal Cont of the switching circuit 3 that switches a high-frequency signal.

### Second Embodiment

In the above-mentioned first embodiment, the positive potential generation circuit 16 and the negative potential generation circuit 17 are each individually provided with a separate clock generator circuit (respectively, the first clock generator 11 and the second clock generator 12). In a second embodiment described below, the positive potential generation circuit 16 and the negative potential generation circuit 17 share one oscillator.

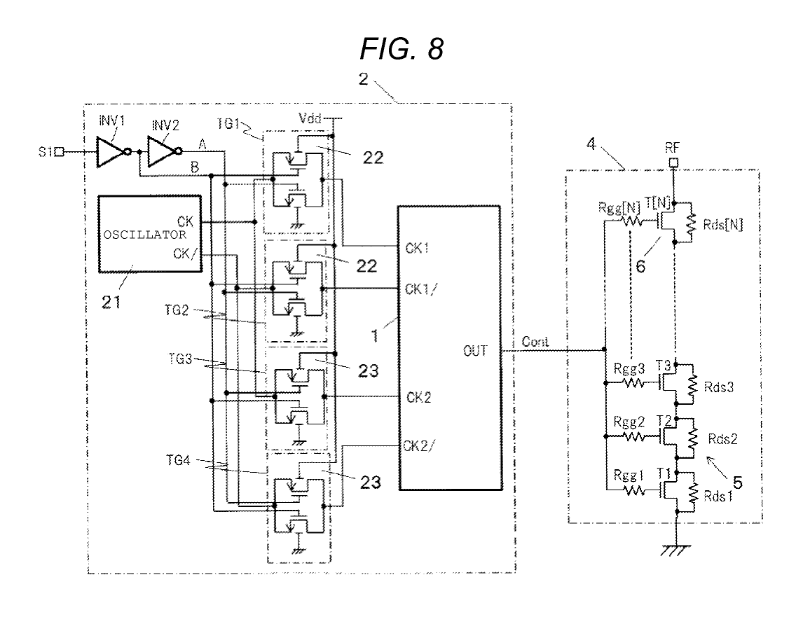

FIG. 8 is a block diagram illustrating a schematic configuration of a switching circuit according to the second embodiment. The switching circuit of FIG. 8 is similar to that in FIG. 1, except that a portion of the internal configuration of the potential conversion circuit 2 is different from that in FIG. 1.

A potential conversion circuit 2 of FIG. 8 includes inverters INV1 and INV2, an oscillator 21, first clock gate units 22, second clock gate units 23, and a charge pump 1. Among these components, the internal configurations of the inverters INV1 and INV2 and the charge pump 1 are in common with those in FIGS. 1 and 8. The oscillator 21 generates reference clock signals CK and CK/ which are synchronized with the first to fourth clock signals CK1, CK1/, CK2, and CK2/. The reference clock signals CK and CK/ are signals of which the phases are inverted from each other.

The first clock gate unit 22 generates the first clock signal CK1 and the second clock signal CK1/ in synchronization with the reference clock signals CK and CK/ when the control signal S1 is high (first logic level), and stops the first clock signal CK1 and the second clock signal CK1/ when the control signal S1 is low (second logic level).

For example, the first clock gate unit 22 includes a first transfer gate TG1 that switches between passing and cutting off of the reference clock signal CK and a second transfer gate TG2 that switches between passing and cutting off of the reference clock signal CK/, in accordance with the logic of the control signal S1. More specifically, the first transfer gate TG1 and the second transfer gate TG2 generates the first clock signal CK1 and the second clock signal CK1/ by passing the reference clock signals CK and CK/ when the control signal S1 is high (first logic level), and stops the first clock signal CK1 and the second clock signal CK1/ by cutting off the reference clock signals CK and CK/ when the control signal S1 is low (second logic level).

The second clock gate unit 23 generates the third clock signal CK2 and the fourth clock signal CK2/ in synchronization with the reference clock signals CK and CK/ when the control signal S1 is low (second logic level), and stops the third clock signal CK2 and the fourth clock signal CK2/ when the control signal S1 is low (second logic level).

For example, the second clock gate unit 23 includes a third transfer gate TG3 that switches between passing and cutting off of the reference clock signal CK and a fourth transfer gate TG4 that switches between passing and cutting off of the reference clock signal CK/, in accordance with the logic of the control signal S1. More specifically, each of the third transfer gate and the fourth transfer gate generates the third clock signal CK2 and the fourth clock signal CK2/ by passing the reference clock signals CK and CK/ when the control signal S1 is low (second logic level), and stops the third clock signal CK2 and the fourth clock signal CK2/ by cutting off the reference clock signals CK and CK/ when the control signal S1 is high (first logic level).

In this manner, because the first to fourth clock signals CK1, CK1/, CK2, and CK2/ are generated using the reference clock signals CK and CK/ generated by the oscillator 21, the required number of oscillators may be reduced as compared to the first embodiment.

In the potential conversion circuit 2 of FIG. 8, the number of oscillators 21 is reduced by one, however, the first clock gate unit 22 and the second clock gate unit 23 are added instead. But the first clock gate unit 22 and the second clock gate unit 23 may be formed using only a small number of MOS transistors, so a reduction in the number of oscillators 21 leads to a net reduction in circuit area even with the inclusion of first clock gate unit 22 and second clock gate unit 23.

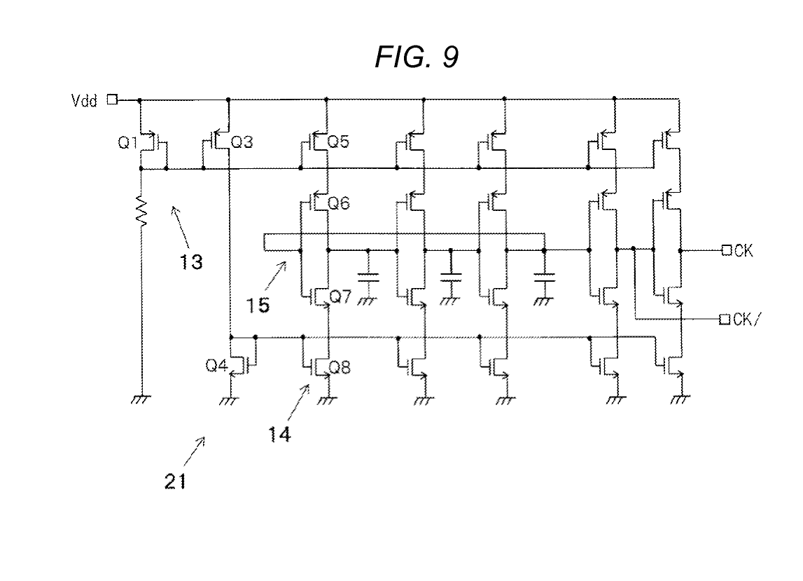

FIG. 9 is a circuit diagram illustrating an internal configuration of the oscillator 21. The oscillator 21 of FIG. 9 differs only from first and second clock generator circuits (elements 11 and 12) depicted in FIG. 2 in that the NMOS transistor Q2 is omitted from the circuit depicted in FIG. 2, and thus the detailed description of the internal components of oscillator 21 will not be given. The circuit configurations of FIGS. 2 and 9 may also be varied.

In this manner, since the switching circuit of FIG. 8 generates the first to fourth clock signals CK1, CK1/, CK2, and CK2/ which are supplied to the positive potential generation circuit 16 and the negative potential generation circuit 17 within the charge pump 1, using the reference clock signal from one oscillator 21, it is possible to reduce the number of oscillators, and to simplify a circuit configuration.

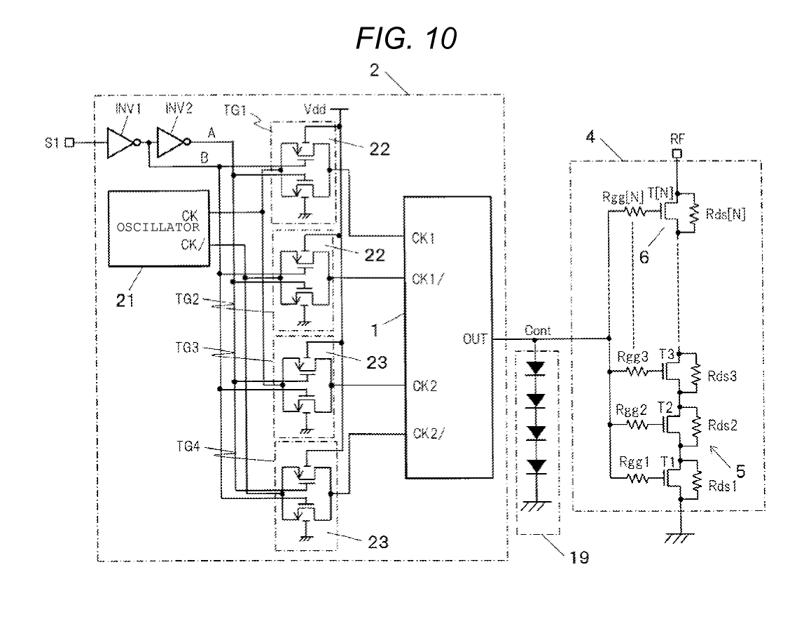

FIG. 10 is a first modified example of the switching circuit of FIG. 8, and is a diagram in which the positive potential clamping circuit 19 is connected to the output node OUT of the potential conversion circuit 2. The positive potential clamping circuit 19 is the same as the positive potential clamping circuit 19 of FIG. 5A. In addition, the same circuit as that of the negative potential clamping circuit 20 of FIG. 5B may be connected to the output node OUT of the potential conversion circuit 2.

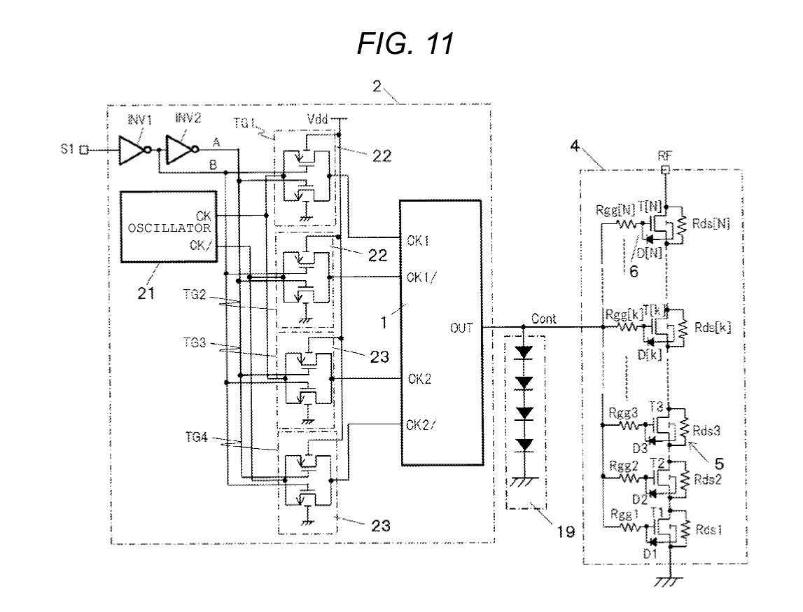

FIG. 11 is a second modified example of the switching circuit of FIG. 8, and is a diagram in which the same diode d[k] as that of FIG. 7 is connected between the body and the gate of each FET within the switching circuit.

In this manner, in the second embodiment, since the first to fourth clock signals CK1, CK1/, CK2, and CK2/ are generated by passing and cutting off the reference clock signal, generated in one oscillator 21, in the first clock gate unit 22 and the second clock gate unit 23, it is possible to reduce the number of oscillators, and to reduce the circuit area of the potential conversion circuit 2.

### Third Embodiment

In a third embodiment described below, a specific through FET group is switched and controlled using the switching control signal Cont which is output from the potential conversion circuit 2 according to the above-mentioned first or second embodiment.

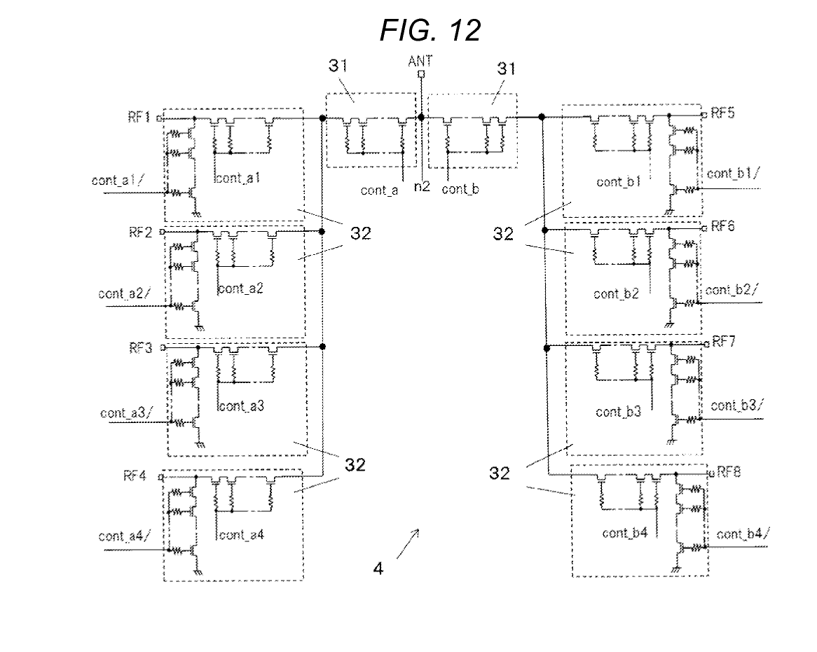

FIG. 12 is a circuit diagram illustrating a detailed configuration of a high-frequency switching unit 4 according to the third embodiment. The high-frequency switching unit 4 of FIG. 12 includes two sets of switch groups which are connected symmetrically to a common signal node n2 of an antenna. Each of the switch groups includes a first hierarchy-through FET group 31 of which one end is connected to the common signal node n2, and a plurality of second hierarchy-through FET groups which are connected between the other end of the first-hierarchy through FET group (a second hierarchy connection node) and a plurality of high-frequency signal nodes RF (RF1, RF2, . . . ) (“RF nodes,” collectively).

In this manner, the formation of a tree type in which the switch group is disposed symmetrically and hierarchically to the common signal node n2 is effective in reduce an insertion loss. However, the first hierarchy-through FET group 31 is located at a place closest to the common signal node n2 of the antenna, and thus in a case of an off-state, the drain-to-source voltage of each FET of the first hierarchy-through FET group 31 becomes higher than the drain-to-source voltage of each FET of the second hierarchy-through FET group 32. For this reason, the off-potential of the switching control signal Cont for turning on and turning off the first hierarchy-through FET group 31 is required to be made lower than the off-potential of the switching control signal Cont of the second hierarchy-through FET group 32. The reason is because, as the off-potential of the switching control signal Cont becomes higher, distortion characteristics at the time of turn-off deteriorate.

Consequently, in the third embodiment, the switching control signal Cont supplied to a plurality of first hierarchy-through FET groups 31, symmetrically disposed, which are located at a position closest to the common signal node n2 of the antenna is generated by the potential conversion circuit 2 according to the first or second embodiment. As described above, the potential conversion circuit 2 according to the first or second embodiment is configured only with diodes and capacitors, and there is no restriction on a breakdown voltage, thereby allowing the off-potential of the switching control signal Cont to be made lower. Thereby, there is no concern that signal distortion may increase at the time of turn-off.

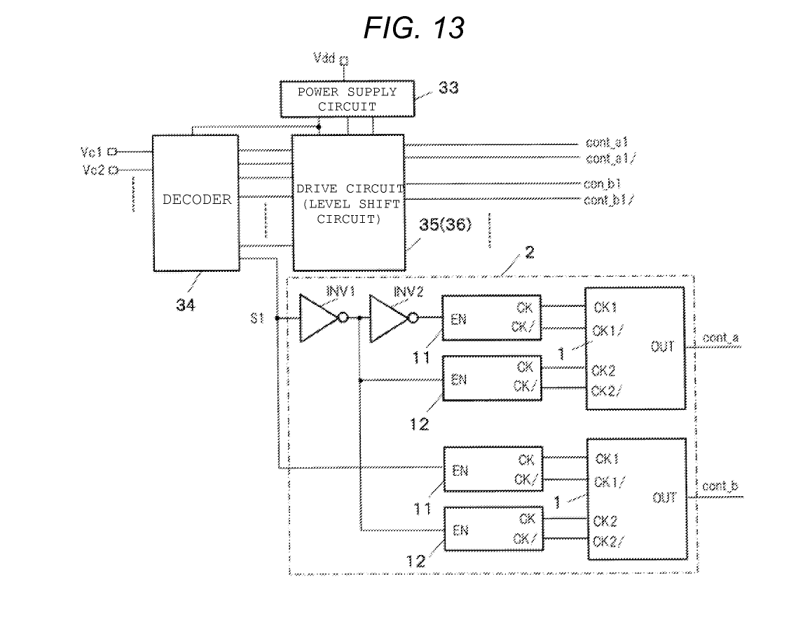

FIG. 13 is a block diagram illustrating a potential conversion circuit 2 and its peripheral circuits according to the third embodiment. The potential conversion circuit 2 of FIG. 13 includes a plurality of charge pumps 1 that generate the switching control signal Cont for each of the plurality of first hierarchy-through FET groups 31 which are connected symmetrically to the common signal node n2 of the antenna. The potential conversion circuit 2 of FIG. 13 includes two charge pumps 1, but requires 2n charge pumps when 2n (n is an integer of 1 or greater) first hierarchy-through FET groups 31 are connected to the common signal node n2.

The peripheral circuits of the potential conversion circuit 2 illustrated in FIG. 13 include a power supply circuit 33, a decoder 34, and a drive circuit 35. The power supply circuit 33 generates a power supply potential which is used by the decoder 34, the drive circuit 35, and the potential conversion circuit 2. The decoder 34 decodes a control voltage (e.g., Vc1, Vc2, etc.) which is input from the outside to generate a control signal S1, and supplies the generated control signal S1 to the potential conversion circuit 2 and the drive circuit 35. The drive circuit 35 includes a level shifter 36 therein, and converts the potential level of the control signal S1 in the level shifter 36 to generate a switching control signal Cont (includes cont_a1, cont_a1/, cont_b1, cont_b1/, . . . ). The switching control signal Cont generated in the drive circuit 35 is used for the on and off control of the second hierarchy-through FET groups 32.

The potential conversion circuit 2 in FIG. 13 includes a set of inverters INV1 and INV2, the first clock generator 11, the second clock generator 12, and the charge pump 1, and is provided with sets of these components corresponding to the number of first hierarchy-through FET groups 31. Each set of the first clock generators 11 generates the first clock signal CK1 and the second clock signal CK1/ of which the phases are inverted from each other at the same timing, and each of the second clock generators 12 generates the third clock signal CK2 and the fourth clock signal CK2/ of which the phases are inverted from each other at the same timing.

Thereby, the plurality of first hierarchy-through FET groups 31 which are connected symmetrically to the common signal node n2 of the antenna are switched on or off and are controlled at the same timing using the output of potential conversion circuit 2 (e.g., signal cont_a, cont_b, etc.).

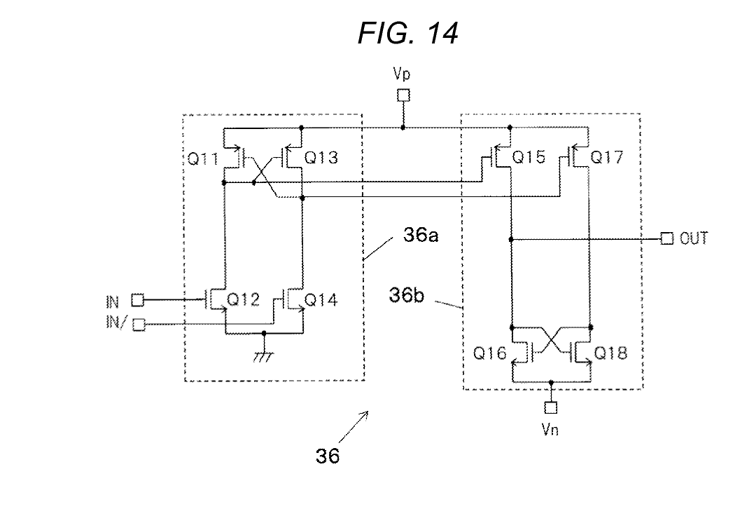

FIG. 14 is a circuit diagram illustrating an example of an internal configuration of the level shifter 36. The level shifter 36 of FIG. 14 includes a first-stage level shifter unit 36a and a post-stage level shifter unit 36b.

The first-stage level shifter unit 36a includes a PMOS transistor Q11 and an NMOS transistor Q12 which are connected in series to each other between a positive potential Vp and a ground line, and a PMOS transistor Q13 and an NMOS transistor Q14 which are likewise connected in series to each other between the positive potential Vp and the ground line. Any decoding signal D[i] is input to the gate of the NMOS transistor Q12, and an inverted signal of the decoding signal D[i] is input to the gate of the NMOS transistor Q14. The PMOS transistors Q11 and Q13 are cross-connected to each other. That is, the gate of the PMOS transistor Q11 is connected to the connection node between the transistors Q13 and Q14, and the gate of the PMOS transistor Q13 is connected to the connection node between the transistors Q11 and Q12.

The post-stage level shifter unit 36b includes a PMOS transistor Q15 and an NMOS transistor Q16 which are connected in series to each other between the positive potential Vp and a negative potential Vn, and a PMOS transistor Q17 and an NMOS transistor Q18 which are likewise connected in series to each other between the positive potential Vp and the negative potential vn.

The NMOS transistors Q16 and Q18 are cross-connected to each other. The gate of the PMOS transistor Q15 is connected to the connection node between the transistors Q11 and Q12, and a signal Cont[i] after potential level conversion is output from the connection node. The gate of the PMOS transistor Q16 is connected to the connection node between the transistors Q13 and Q14, and an inverted signal Cont[i]/ of the signal Cont[i] after potential level conversion is output from the connection node.

According to the present example, the charge pump 1 and the like illustrated in FIG. 1 (or other embodiments) are separate from the level shifter 36 in the drive circuit 35. The potential conversion circuit 2 is required only to control the first hierarchy-through FET groups 31. Therefore, overall circuit area of the switching circuit does not increase that much because there are relatively few first hierarchy-through FET groups 31.

The internal configuration of the potential conversion circuit 2 in FIG. 13 may be formed similarly to that in FIG. 8 rather than FIG. 1. In addition, the positive potential clamping circuit 19 and/or the negative potential clamping circuit 20 may be connected to the output node OUT of the potential conversion circuit 2 in FIG. 13.

In this manner, in the third embodiment, since the switching control signal Cont (including cont_a and cont_a/) for controlling the first hierarchy-through FET group 31 is generated in the potential conversion circuit 2 according to the first or second embodiment, it is possible to generate a switching control signal Cont having a large amplitude without increasing signal distortion.

### Fourth Embodiment

Ina fourth embodiment, the switching control signal Cont which is output from the potential conversion circuit 2 according to the first or second embodiment mentioned above is supplied to the through FET group that satisfies conditions different from those in the third embodiment.

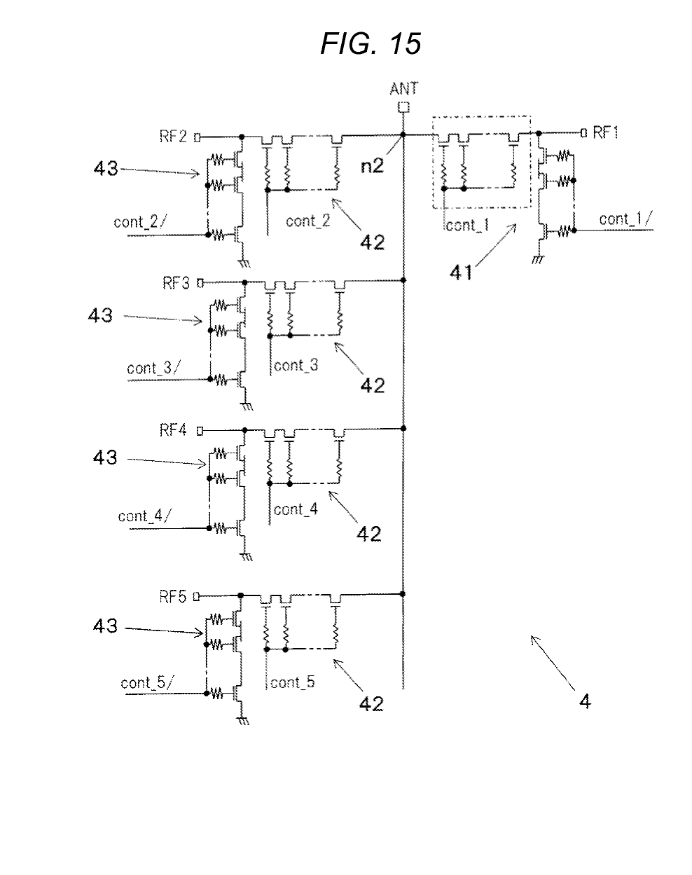

FIG. 15 is a circuit diagram illustrating a detailed configuration of a high-frequency switching unit 4 according to the fourth embodiment. The high-frequency switching unit 4 of FIG. 15 includes a first through FET group 41 which is connected to the common signal node n2 of the antenna, a plurality of second through FET groups 42 which are likewise connected to the common signal node n2, and a plurality of shunt FET groups 43 which are respectively connected between high-frequency signal nodes RF2 to FR5 and ground nodes.

The first through FET group 41 is controlled (switched on and off) by the switching control signal Cont (cont_1) generated in the potential conversion circuit 2 according to the first or second embodiment, and the second through FET group 42 is controlled on and off by the switching control signal Cont (cont_2, cont_3, cont_4, cont_5) generated by a level shifter 36 (illustrated in FIG. 14) within drive circuit 35.

The number of connection stages of FETs in the first through FET group 41 is less than the number of connection stages of FETs in each of the plurality of second through FET groups 42. That is, the number of FETs connected in series within each first through FET group 41 is less than the number of FETs connected in series within each second through FET group 42. As the number of connection stages of FETs becomes less, harmonic distortion generated at the time of turn-on is reduced. Generally, when the number of stages which are connected in series to each other is set to Nstack, harmonic distortion (dB) generated at the time of turn-on follows a scaling law expressed by 20 log(Nstack). Thus, the harmonic distortion generated when a first through FET group 41 is turned on is smaller than the harmonic distortion generated when a second through FET group 42 is turned on. That is, because the number of FETs connected in series in each first through FET group 41 is less than the number of FETs connected in series in each second through FET group 42, the first through FET groups 41 cause less harmonic distortion when switched on than do the second through FET groups 42 when switched on.

Here, in secondary harmonic distortion of the harmonic distortion, a component which is generated by an on-state FET is dominant. Therefore, according to the fourth embodiment, secondary harmonic distortion when a high-frequency signal node RF1 connected to the first through FET group 41 is in an electrical conduction state becomes satisfactory.

In addition, the gate width of each FET in the first through FET group 41 may be made larger than the gate width of each FET in the second through FET group 42. Thereby, it is possible to further reduce the secondary harmonic distortion generated when the first through FET group 41 in an on-state.

As described above, as the number of stack stages (FETs connected in series) becomes smaller, the harmonic distortion in an on-state improves, but the off-potential tolerance deteriorates. However, in the fourth embodiment, since the first through FET group 41 is driven by the potential conversion circuit 2 illustrated in FIG. 1 (or the like), it is possible to make an off-potential applied to the control terminals of the FETs to be lower than the potential level generated by the level shifter 36, and thus it is possible to prevent the off-potential tolerance from deteriorating.

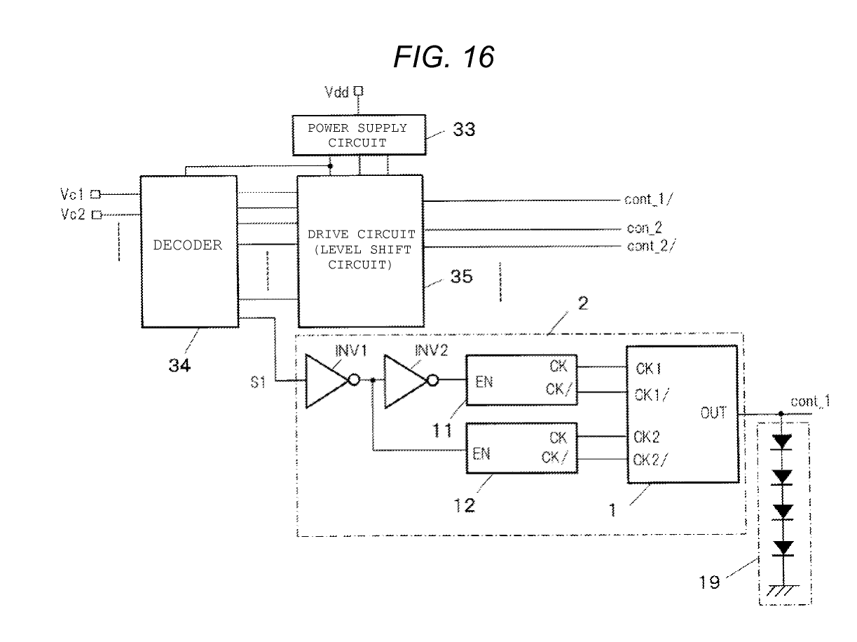

FIG. 16 is a block diagram illustrating a potential conversion circuit 2 and peripheral circuits according to the fourth embodiment. The potential conversion circuit 2 of FIG. 16 includes inverters INV1 and INV2, a first clock generator 11, a second clock generator 12, and a charge pump 1. The switching control signal generated in the charge pump 1 is supplied to the gate of the first through FET group 41. The configurations of the peripheral circuits of FIG. 16 are the same as those in FIG. 13.

In the fourth embodiment, as is the case with the third embodiment, the potential conversion circuit 2 is required separately from the level shifter 36, and a circuit area increases. However, since the first through FET group 41 is provided only when criteria for the secondary harmonic distortion are strict (e.g., only for a sub-set of RF nodes in the switching circuit), and the switching control signal (cont_1) from the potential conversion circuit 2 is supplied only to the first through FET groups 41. Therefore, in the entirety of the switching circuit, an increase in circuit area by providing the potential conversion circuit 2 will be relatively insignificant in this fourth embodiment.

In this manner, in the fourth embodiment, the switching control signal for the through FET group(s) (first through FET group 41) having a small number of series-connected FETs is generated in the charge pump 1 within the potential conversion circuit 2, and the switching control signals (cont_1/, con_2, cont_2/, etc.) of the other through FET groups are generated in the level shifter 36. Therefore, when the restriction of the secondary harmonic distortion is strict for one or more particular RF nodes, the number of FETs in a through FET group connected between the particular RF node and the common antenna node (n2) can be reduced and the driving of the through FET group can be performed using a switching control signal from the potential conversion circuit 2 to prevent off-potential tolerance of the through FET group from deteriorating because the magnitude of the potential supplied by the potential conversion circuit 2 is larger than the potential supplied by the level shifter 36.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A charge pump, comprising:
a positive potential generation circuit connected between a reference potential node and an output node and including a first plurality of rectifying elements connected in series between the reference potential node and the output node, each adjacent pair of rectifying elements in the first plurality having a capacitor with a first end connected to a node between the adjacent pair and, for a first group of adjacent pairs, a second end of the capacitor is connected to a first clock signal port and, for a second group of adjacent pairs, a second end of the capacitor is connected to a second clock signal port, the adjacent pairs in the first and second groups alternating in series with each other; and
a negative potential generation circuit connected between the reference potential node and the output node and including a second plurality of rectifying elements connected in series between the reference potential node and the output node, each adjacent pair of rectifying elements in the second plurality having a capacitor with a first end connected to a node between the adjacent pair and, for a first group of adjacent pairs, a second end of the capacitor is connected to a third clock signal port and, for a second group of adjacent pairs, a second end of the capacitor is connected to a fourth clock signal port, the adjacent pairs in the first and second groups alternating in series with each other, wherein
the first and second plurality of rectifying elements are connected in opposite directions between the output node and the ground node.

2. The charge pump according to claim 1, further comprising:
a positive potential clamping circuit including a plurality of diodes connected in series anode to cathode between the output node and the ground node.

3. The charge pump according to claim 2, further comprising:
a negative potential clamping circuit including a plurality of diodes connected cathode to anode in series between the output node and the ground node.

4. The charge pump according to claim 1, further comprising:
a negative potential clamping circuit including a plurality of diodes connected cathode to anode in series between the output node and the ground node.

5. The charge pump according to claim 1, further comprising:
a filter connected to the output node.

6. The charge pump according to claim 5, wherein the filter is a low pass filter.

7. A potential conversion circuit, comprising:
a charge pump including:
a positive potential generation circuit connected between a reference potential node and an output node and including a first plurality of rectifying elements connected in series between the reference potential node and the output node, each adjacent pair of rectifying elements in the first plurality having a capacitor with a first end connected to a node between the adjacent pair and, for a first group of adjacent pairs, a second end of the capacitor is connected to a first clock signal port and, for a second group of adjacent pairs, a second end of the capacitor is connected to a clock signal port, the adjacent pairs in the first and second groups alternating in series with each other; and
a negative potential generation circuit connected between the reference potential node and the output node and including a second plurality of rectifying elements connected in series between the reference potential node and the output node, each adjacent pair of rectifying elements in the second plurality having a capacitor with a first end connected to a node between the adjacent pair and, for a first group of adjacent pairs, a second end of the capacitor is connected to a third clock signal port and, for a second group of adjacent pairs, a second end of the capacitor is connected to a fourth clock signal port, the adjacent pairs in the first and second groups alternating in series with each other, wherein
the first and second plurality of rectifying elements are connected in opposite directions between the output node and the ground node; and
a clock signal generator configured to:
generate a first clock signal and a second clock signal having phases that are inverted from each other when a first control signal supplied at a first control signal node is a first logic level, and
generate a third clock signal and a fourth clock signal having phases that are inverted from each other when the first control signal is a second logic level, wherein
the first and second clock signals are respectively supplied to the first and second clock signal ports only when the first control signal is the first logic level, and
the third and fourth clock signals are respectively supplied to the third and fourth clock signal ports only when the first control signal is the second logic level.

8. The circuit according to claim 7, wherein the clock generator includes:
a first clock generator configured to generate the first clock signal and the second clock signal when the first control signal is the first logic level, and to stop generating the first clock signal and the second clock signal when the first control signal is the second logic level; and
a second clock generator configured to generate the third clock signal and the fourth clock signal when the first control signal is the second logic level, and to stop generating the third clock signal and the fourth clock signal when the first control signal is the first logic level.

9. The circuit according to claim 7, wherein the clock generator includes:
an oscillator that generates a reference clock signal;
a first clock gate unit connected between the oscillator and the charge pump and configured to generate the first clock signal and the second clock signal using the reference clock signal when the first control signal is the first logic level, and to stop generating the first clock signal and the second clock signal when the first control signal is the second logic level; and
a second clock gate unit connected between the oscillator and the charge pump and configured to generate the third clock signal and the fourth clock signal using the reference clock signal when the first control signal is the second logic level, and to stop generating the third clock signal and the fourth clock signal when the first control signal is the first logic level.

10. A switching circuit, comprising:
a charge pump including:
a positive potential generation circuit connected between a reference potential node and an output node and including a first plurality of rectifying elements connected in series between the reference potential node and the output node, each adjacent pair of rectifying elements in the first plurality having a capacitor with a first end connected to a node between the adjacent pair and, for a first group of adjacent pairs, a second end of the capacitor is connected to a first clock signal port and, for a second group of adjacent pairs, a second end of the capacitor is second clock signal port, the adjacent pairs in the first and second groups alternating in series with each other; and
a negative potential generation circuit connected between the reference potential node and the output node and including a second plurality of rectifying elements connected in series between the reference potential node and the output node, each adjacent pair of rectifying elements in the second plurality having a capacitor with a first end connected to a node between the adjacent pair and, for a first group of adjacent pairs, a second end of the capacitor is connected to a third clock signal port and, for a second group of adjacent pairs, a second end of the capacitor is connected to a fourth clock signal port, the adjacent pairs in the first and second groups alternating in series with each other, wherein
the first and second plurality of rectifying elements are connected in opposite directions between the output node and the ground node;
a clock signal generator configured to:
to generate a first clock signal and a second clock signal having phases that are inverted from each other when a first control signal supplied at a first control signal node is a first logic level, and
to generate a third clock signal and a fourth clock signal having phases that are inverted from each other when the first control signal is a second logic level, wherein
the first and second clock signals are respectively supplied to the first and second clock signal ports only when the first control signal is the first logic level, and
the third and fourth clock signals are respectively supplied to the third and fourth clock signal ports only when the first control signal is the second logic level; and
a switching unit configured to switch between a conducting state and a non-conducting state according to a potential at the output node of the charge pump.

11. The switching circuit according to claim 10, wherein the switching unit includes:
a plurality of first hierarchy switching units connected to a common signal node, each first hierarchy switching unit including a plurality of switching elements connected in series between the common signal node and a second hierarchy connection node, the plurality of switching elements being switched between on and off states by the potential at the output node of the charge pump; and
a plurality of second hierarchy switching units each connected between an RF node and one of the second hierarchy connection nodes.

12. The switching circuit according to claim 11, further comprising:
a level shifter configured to provide a control signal to each of the plurality of second hierarchy switching units, wherein the plurality of second hierarchy switching units are switched between on and off states by the control signal provided by the level shifter.

13. The switching circuit according to claim 10, further comprising:
a positive potential clamping circuit including a plurality of diodes connected in series anode to cathode between the output node and the ground node.

14. The switching circuit according to claim 10, further comprising:
a negative potential clamping circuit including a plurality of diodes connected cathode to anode in series between the output node and the ground node.

15. The charge pump according to claim 10, further comprising:
a filter connected to the output node.

16. The switching circuit according to claim 10, wherein the switching unit includes:
a common signal node;
a first switching group connected between the common signal node and a first RF node and including a first plurality of switching elements connected in series;
a second switching group connected between the common node and a second RF node and including a second plurality of switching elements connected in series, wherein
the number of switching elements in the first plurality is less than the number of switching elements in the second plurality,
the first switching group has a gate connected to the output node of the charge pump, and
the second switching group has a gate connected to an output of a level shifter.

17. The switching circuit according to claim 16, wherein the first plurality of switching elements has a gate width that is greater than a gate width of the second plurality of switching elements.

18. The switching circuit according to claim 16, further comprising a plurality of second switching groups.

19. The switching circuit according to claim 10, wherein the clock generator includes:
a first clock generator configured to generate the first clock signal and the second clock signal when the first control signal is the first logic level, and to stop generating the first clock signal and the second clock signal when the first control signal is the second logic level; and
a second clock generator configured to generate the third clock signal and the fourth clock signal when the first control signal is the second logic level, and to stop generating the third clock signal and the fourth clock signal when the first control signal is the first logic level.

20. The switching circuit according to claim 10, wherein the clock generator includes:
an oscillator that generates a reference clock signal;
a first clock gate unit connected between the oscillator and the charge pump and configured to generate the first clock signal and the second clock signal using the reference clock signal when the first control signal is the first logic level, and to stop generating the first clock signal and the second clock signal when the first control signal is the second logic level; and
a second clock gate unit connected between the oscillator and the charge pump and configured to generate the third clock signal and the fourth clock signal using the reference clock signal when the first control signal is the second logic level, and to stop generating the third clock signal and the fourth clock signal when the first control signal is the first logic level.
